(19) United States
(12) Patent Application Publication
(10) Pub. No.: US 2025/0031328 A1
(43) Pub. Date: Jan. 23, 2025

(54) ARTICULATING LINK MECHANISM FOR AN ELECTRICAL ENCLOSURE

(71) Applicant: Eaton Intelligent Power Limited, Dublin (IE)

(72) Inventors: Prasad Ashok Dharmadhikari, Nagar Pune (IN); Bhushan Kadu, Pune (IN); Travis Vernon Spoone, Greenwood, SC (US); Michael Pearce, Plum Branch, SC (US); Amar Ashok Pawar, Hadapsar Pune (IN)

(21) Appl. No.: 18/767,380

(22) Filed: Jul. 9, 2024

(30) Foreign Application Priority Data
Jul. 21, 2023 (IN) 202311049354

(51) Int. Cl. H05K 5/02; E05D 15/28; H05K 5/03

(52) U.S. Cl. CPC H05K 5/0226; E05D 15/28; H05K 5/03

(57) ABSTRACT

An apparatus includes: a main body including an interior configured to receive an electrical apparatus, the main body including at least one opening to the interior; and a door configured to overlap the at least one opening to the interior in a first position and to not overlap the at least one opening to the interior in a second position. The apparatus also includes a mounting assembly that includes: a first articulating connection attached to the main body; a second articulating connection attached to the moveable door; and a link between the first articulating connection and the second articulating connection. The mounting assembly is configured to permit the door to move laterally relative to the main body and to rotate about the second articulating connection to transition from the first position and the second position.

### CROSS-REFERENCE TO RELATED APPLICATION

This application claims priority to Indian patent application Ser. No. 20/231,1049354, filed Jul. 21, 2023 and titled ARTICULATING LINK MECHANISM FOR AN ELECTRICAL ENCLOSURE, which is incorporated herein by reference in its entirety.

### TECHNICAL FIELD

This disclosure relates to an articulating link mechanism for an electrical enclosure.

### BACKGROUND

An electrical apparatus may be enclosed in a housing to protect the electrical apparatus.

### SUMMARY

In one aspect, an apparatus includes: a main body including an interior configured to receive an electrical apparatus, the main body including at least one opening to the interior; and a door configured to overlap the at least one opening to the interior in a first position and to not overlap the at least one opening to the interior in a second position. The apparatus also includes a mounting assembly that includes: a first articulating connection attached to the main body; a second articulating connection attached to the moveable door; and a link between the first articulating connection and the second articulating connection. The mounting assembly is configured to permit the door to move laterally relative to the main body and to rotate about the second articulating connection to transition from the first position and the second position.

Implementations may include one or more of the following features.

Each of the first articulating connection and the second articulating connection may be a pin joint. In these implementations, a first pin passes through the link and is attached to the main body to connect the link and the main body, and a second pin passes through the link and is attached to the door to connect the link and the door.

The mounting assembly may be a first mounting assembly, and the apparatus also includes a second mounting assembly. The first mounting assembly may be attached to one end of the door and to one end of the main body, and the second mounting assembly may be attached to a different end of the door and to a different end of the main body. The door may include a first door and a second door, and the first mounting assembly may be attached to the first door and the main body, and the second mounting assembly may be attached to the second door and the main body.

The apparatus also may include a hinge housing configured to receive an end of the link, and the link may be configured to move through an arc in the hinge housing.

The first position may be a closed position, and the apparatus also may include a door fastening system configured to secure the door to the main body when the door is in the closed position. The apparatus also may include a motion limiting system that extends from the door and is configured to be attached to the door fastening system when the door is in the second position, and, when attached to the door fastening system, the motion limiting system prevents the door from moving from the second position to the first position.

The door may be substantially planar, the door may be in a first plane in the first position, and the door may be in a second plane that is orthogonal to the first plane in the second position.

The main body may include a plurality of sides, and the mounting assembly may be configured to allow the door to move laterally relative to two adjacent sides of the main body. The two adjacent sides may be two orthogonal sides of the main body.

In another aspect, a mounting assembly for a housing of an electrical apparatus includes: a link; a first connection assembly configured to attach to a main body of the housing and to the link; and a second connection assembly configured to attach to a door and to the link. The mounting assembly is configured such that the door rotates relative to an axis of the second connection assembly and moves laterally relative to the main body.

The mounting assembly may be configured to allow the door to move laterally relative to two orthogonal sides of the main body. The first connection assembly may include a first pin assembly that passes through the link at attaches to the main body; the second connection assembly may include a second pin assembly that passes through the link and attaches to the door; and the link may be configured to rotate relative to the first pin assembly and the second pin assembly. The mounting assembly also may include a hinge housing and a bearing, and the first pin assembly may be attached to the hinge housing with the bearing between the link and an inner surface of the hinge housing.

In another aspect, a system includes: an electrical apparatus; and a housing for the electrical apparatus. The housing includes: a main body including an interior; a door configured to move between a closed position and an opened position, where the electrical apparatus is enclosed in the interior when the door is in the closed position; and a mounting assembly including: a first articulating connection attached to the main body; a second articulating connection attached to the moveable door; and a link attached to the first articulating connection and the second articulating connection. The mounting assembly is configured to permit the door to move laterally relative to the main body and to rotate about the second articulating connection to transition the door from the closed position to the opened position.

Implementations may include one or more of the following features.

The system also may include a limiting apparatus that prevents the door from moving out of the opened position until the limiting apparatus is removed.

The link may be a bar that extends from a first end to a second end; and the system also may include: a hinge housing attached to a top side of the main body, and a bearing. The first end of the bar is in the hinge housing with the bearing between the bar and an inner side of the hinge housing.

The main body may include a plurality of sides, and the mounting assembly may be configured to allow the door to move laterally relative to two adjacent sides of the main body. Implementations of any of the techniques described herein may include a system, an apparatus, a mounting assembly, or a method. The details of one or more implementations are set forth in the accompanying drawings and the description below. Other features will be apparent from the description and drawings, and from the claims.

### DRAWING DESCRIPTION

FIG. 1A is an example of a housing for an electrical apparatus.

FIGS. 1B-1D are top views of the housing of FIG. 1A.

FIGS. 2A-2D are perspective views of another housing for an electrical apparatus.

FIGS. 3A-3D are perspective views of another housing for an electrical apparatus.

FIGS. 4A-4D are perspective views of another housing for an electrical apparatus.

FIGS. 5A, 5B, 5C show top, front, and side views, respectively, of another housing for an electrical apparatus with a door in the closed position.

FIGS. 5D, 5E, 5F show top, front, and side views, respectively, of the housing of FIGS. 5A-5C with the door in an interim position.

FIG. 5G, 5H, 5I show top, front, and side views, respectively, of the housing of FIGS. 5A-5F with the door in the fully open position.

FIG. 6 is a perspective view of an example of a mounting assembly and a hinge housing for a housing for an electrical apparatus.

FIGS. 7A and 7B are perspective views of another housing for an electrical apparatus.

### DETAILED DESCRIPTION

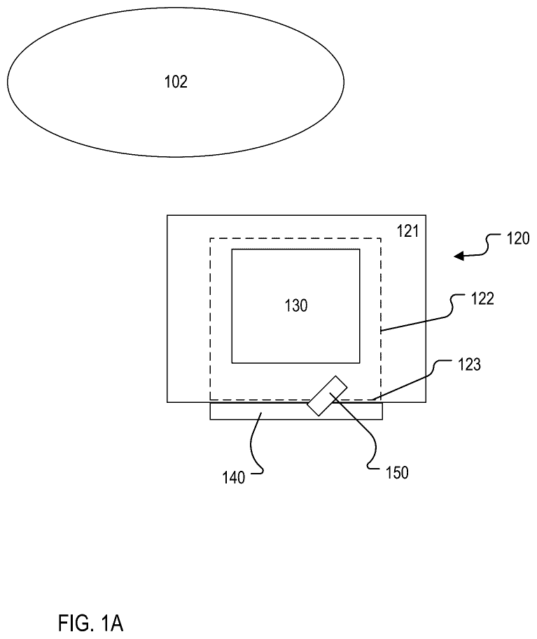

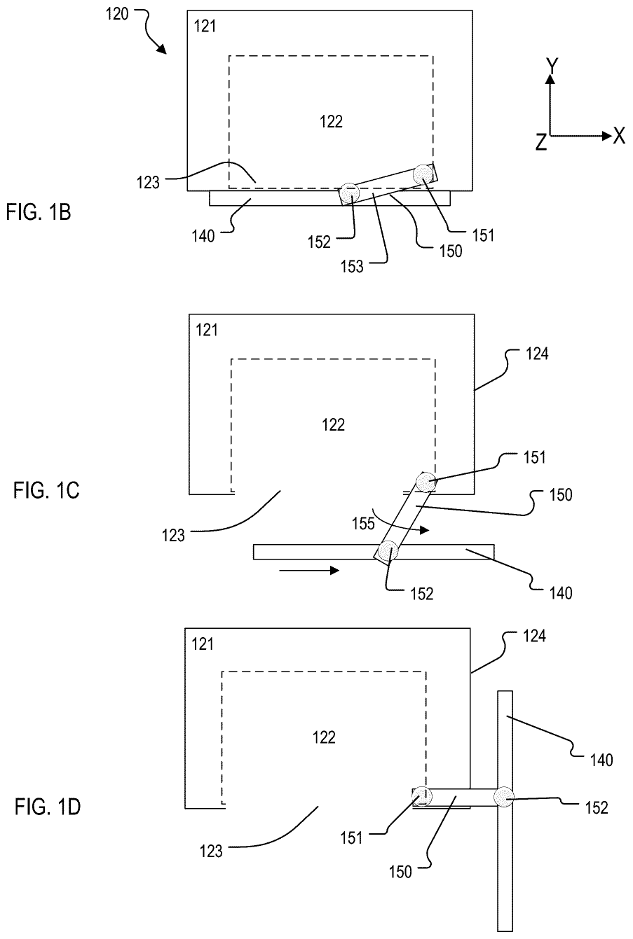

FIG. 1A is an example of a housing 120 that holds an electrical apparatus 130 in an interior 122. The electrical apparatus 130 may be any type of electrical apparatus and may be a multi-phase electrical apparatus. Specific examples of the electrical apparatus 130 include, without limitation, a capacitor bank, a network protector, a circuit breaker, a recloser, a disconnect switch, a power converter, a transformer, one or more surge arresters, or a combination of such devices. The electrical apparatus 130 may be a three-phase apparatus or a single-phase apparatus. The interior 122 may include racks, shelves, mounting points, and/or other structures (not shown) to hold the electrical apparatus 130 in the interior 122.

The electrical apparatus 130 may be connected to an alternating current (AC) power system or grid 102 by an electrical connection (such as a distribution line). The electrical grid 102 is a multi-phase electrical network that provides electricity to commercial, industrial, government, and/or residential customers. The electrical grid 102 may have an operating voltage of, for example, at least 1 kilovolt (kV), up to 34.5 kV, up to 38 kV, or 69 kV or higher, and may operate at a fundamental frequency of, for example, 50 or 60 Hertz (Hz). The grid 102 may include, for example, one or more transmission lines, distribution lines, electrical cables, transformers, generators, renewable resources, distributed energy resources, and/or any other mechanism for transmitting, generating, or consuming electricity.

The housing 120 includes a main body 121 and a door 140 that is attached to the main body 121 by a mounting assembly 150. The main body 121 and door 140 may be made of any rugged solid material, such as, for example, steel. The door 140 is relatively heavy. For example, the door 140 may weigh about 150 to 180 pounds.

In the example of FIG. 1A, the door 140 is in a first position (or closed position) that covers an opening 123 to the interior 122. When the door 140 is in the first position, the interior 122 and the electrical apparatus 130 in the interior 122 are not accessible from an exterior of the housing 120.

As discussed below, the mounting assembly 150 allows the door 140 to be translated relative to the main body 121 and rotated such that the door 140 can be moved from the first position to a second position that allows access to the interior 122. As compared to a traditional mounting assembly that would only allow the door 140 to move or swing through an arc, the mounting assembly 150 (which allows the door 140 to translate and rotate) reduces the amount of space that the door 140 moves through when transitioning from the closed position and the open position and from the open position to the closed position. Thus, the mounting assembly 150 allows the housing 120 and the electrical apparatus 130 to be used in smaller spaces and/or frees up room in limited spaces such that additional equipment may also be installed.

FIGS. 1B-1D are top views of the housing 120 in the X-Y plane. The mounting assembly 150 includes a first articulating connection 151, a second articulating connection 152, and a link 153 that extends between the connections 151 and 152. The first articulating connection 151 connects the link 153 to the main body 121. The second articulating connection 152 connects the link 153 to the door 140.

The first articulating connection 151 and the second articulating connection 152 are any kind of connection assembly that connects two or more elements and allows the elements to rotate relative to each other. For example, each of the connections 151 and 152 may be a pin joint with pins that extend along the Z axis (into and out of the page in FIGS. 1B-1D).

FIG. 1B shows the housing 120 with the door 140 in the closed position. The door 140 covers the opening 123 such that the interior 122 is not accessible from an exterior of the housing 120. To access the interior 122, force is applied to the door 140 in the-Y direction. The door 140 separates from the main body 121, and the link 153 rotates counterclockwise about the first connection 151 along an arc 155 in the X-Y plane. The door 140 also moves laterally in the X direction to the interim position shown in FIG. 1C. To fully open the door 140, a force in the X direction is applied to the door 140 such that the link 153 continues to rotate along the arc 155 until the link 153 extends substantially along the X axis. The door 140 is then rotated counterclockwise about the second connection 152 such that the door 140 extends along the Y axis and is substantially parallel to a side 124 of the housing 120 and the housing 120 is fully open, as shown in FIG. 1D.

To close the housing 120, the door 140 is rotated in the clockwise direction about the second connection 152 and along the arc 155 in the clockwise direction to the interim position shown in FIG. 1D. A force in the −X direction is then applied to the door 140, causing the door 140 to move in the −X direction while the link 153 rotates farther along the arc 155 in the clockwise direction until the door 140 is aligned with the opening 123. Once the door 140 is aligned with the opening 123, a force is applied in the Y direction until the door 140 contacts the main body 121 and the door 140 covers the opening 123 (FIG. 1B).

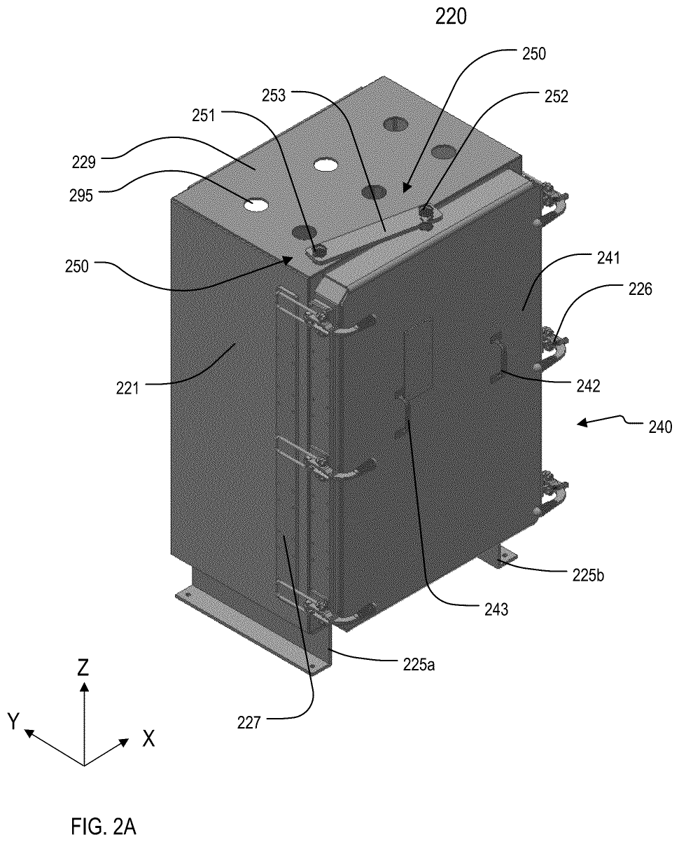

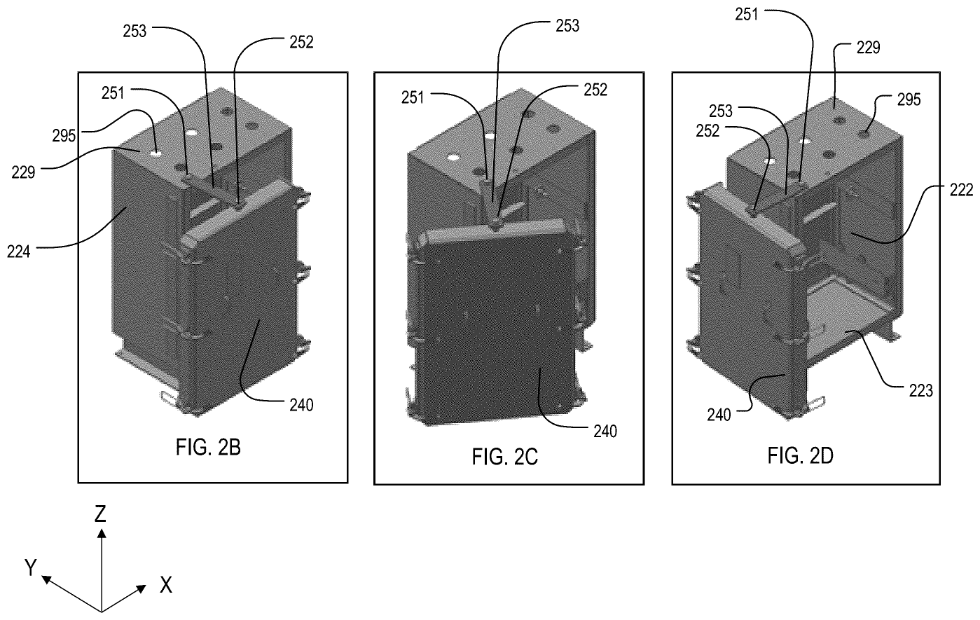

FIGS. 2A-2D are perspective views of a housing 220. The housing 220 includes a main body 221 and a door 240 that is mounted on the main body 221 by a mounting assembly 250. The mounting assembly 250 includes a link 253, a connection point 251 that connects the link 253 to the main body 221, and a connection point 252 that connects the link 253 to the door 240. The connection point 251 and the connection point 252 are pin joints.

FIG. 2A shows the housing 220 with the door 240 in the closed position. FIGS. 2B and 2C show the housing 220 with the door 240 in two different interim positions. FIG. 2D shows the door 240 in the fully open position. In the closed position, clamps 226 secure the door 240 to the main body 221. The clamps 226 may be attached to the main body 221 at bolt or latch blocks 227 that extend in the Z direction on both sides of the main body 221. To open the door 240, the clamps 226 are opened or removed. A force is then applied to the door 240 in the −Y direction. The force may be applied by a human operator. For example, the operator may grasp handles 242 and 243, which are on an exterior surface 241 of the door 240, and pull the handles 242 and 243 in the −Y direction to separate the door 240 from the main body 221. In another example the operator may grasp the clamps 226 in the −Y direction to separate the door 240 from the main body 221. Moreover, the door 240 may be implemented without the handles 242 and 243. For example, the door 240 may be moved by with a tool that is not part of the housing 220, such as a clamp or latch, that an operator uses to grasp the door 240.

Referring also to FIG. 2B, applying the force to the door 240 in the −Y direction causes the door 240 to move in the −Y direction away from the main body 221. The link 253 rotates in the clockwise direction in the X-Y plane about the connection point 251, and the door 240 moves laterally in the −X direction relative to the main body 221 to the interim position shown in FIG. 2B. Referring also to FIG. 2C, the operator rotates the door 240 clockwise in the X-Y plane about the connection point 252 (which extends along the Z axis). The door 240 is rotated clockwise about the connection point 252 until the door 240 extends along the Y axis. Referring to FIG. 2D, the door 240 is pushed in the Y direction such that link 253 rotates in the X-Y plane until it extends substantially along the X axis.

FIG. 2D shows the door 240 in the fully open position. In the fully open position, an interior 222 is accessible and the door 240 does not overlap with any part of the opening 223 to the interior 222. The door 240 can be returned to the closed position (FIG. 2A) by following the procedure in reverse.

As compared to a housing that has a movable door mounted by a mounting arm that only moves the door through an arc, the mounting assembly 250 allows the door 240 to move through a smaller volume during the opening and closing procedures. Moreover, in the fully open position, the door 240 is held in a manner that also takes up less space than a configuration in which the door is held at, for example, a 45- or 90-degree angle relative to the main body in the open position. Additionally, the configuration of the mounting assembly 250 allows for complete rotation of the door 240, even beyond 90° relative to the opening 223, and thus facilitates easy access to the interior 222.

The housing 220 includes additional features. For example, the main body 221 includes openings 295 (only one of which is labeled) that pass through the sidewall of the main body 221 to provide air flow and thermal management or to allow bushings of an electrical device in the interior 222 to be accessible from the exterior of the housing 220. In the example shown in FIGS. 2A-2D, the openings 295 pass through a top side 229 of the main body 229. However, other openings for air flow and/or bushings may pass through other portions of the main body. Moreover, although FIGS. 2A-2D show six openings 295 in the top side 229, the top side 229 may include more or fewer of the openings 295.

The main body 221 is supported by mounting stands 225a and 225b. In the example shown, the mounting stands 225a and 225b are flanges that may be used to secure the housing 220 to a floor or other surface.

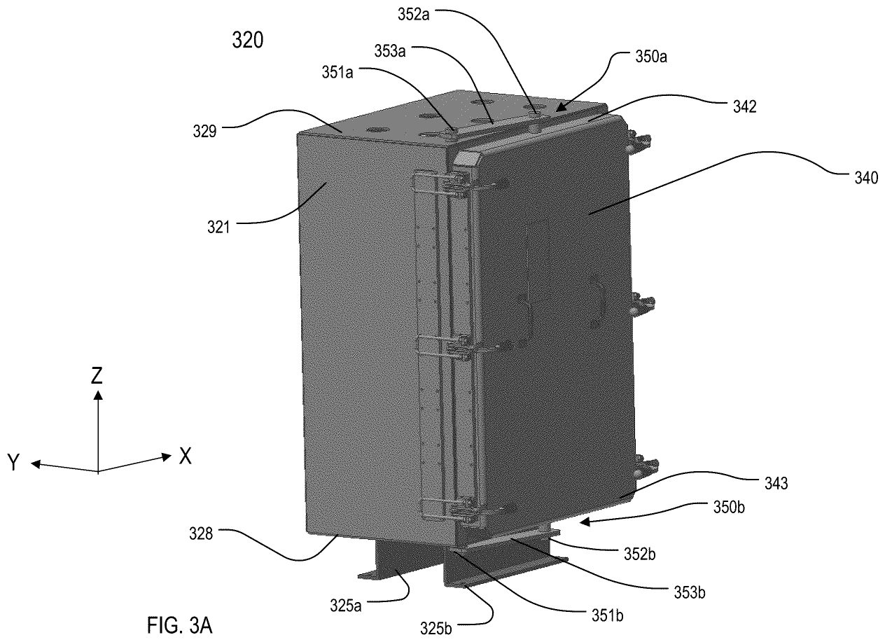

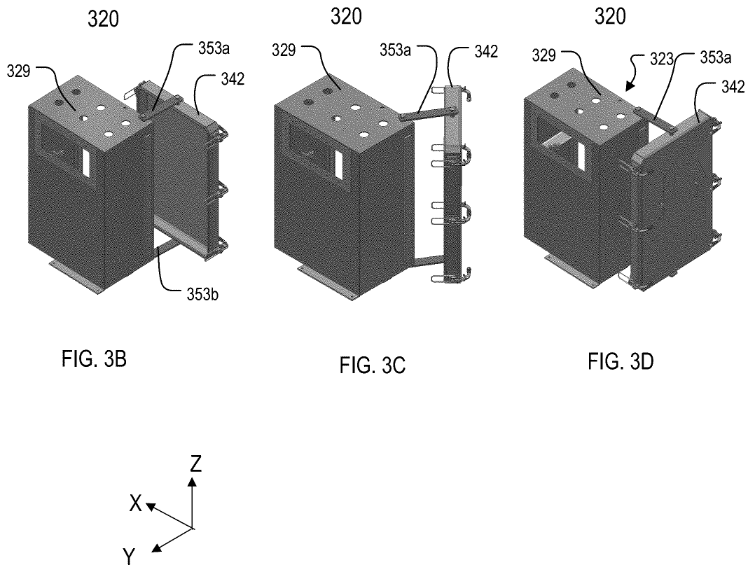

FIG. 3A is a perspective view of another housing 320. The housing 320 includes a main body 321 and a door 340. FIG. 3A shows the door 340 in the closed position. The housing 320 is similar to the housing 220 (FIGS. 2A-2D), except the housing 320 includes two mounting assemblies 350a and 350b, each of which includes two pin joints. Using two mounting assemblies provides additional strength and support to the door 340.

The door 340 has a top side 342 and a bottom side 343. The main body 321 is a parallelepiped with one side being an opening 323 (FIG. 3D) that extends in the X-Z plane. When the door 340 is in the closed position (FIG. 3A), the door 340 covers the opening 323. The main body 321 includes a bottom side 328 and a top side 329, each of which extend in the X-Y plane. The mounting assembly 350a includes a connection point 351a, which connects a link 353a and the top side 329 of the main body 321, and a connection point 352a, which connects the link 353a to the top side 342 of the door 340. The mounting assembly 350b has the same configuration but is connected to the bottom side 328 of the main body 321 and the bottom side 343 of the door 340.

FIGS. 3B and 3C show the door 340 in an interim position. FIG. 3D shows the door 340 in the fully open position. The door 340 is opened and closed using the procedure discussed above with respect to FIGS. 2A-2D, with both the mounting assembly 350a and the mounting assembly 350b moving the manner similar to that discussed above with respect to the mounting assembly 250.

The housing 320 also includes mounting stands 325a and 325b that extend from the bottom side 328 of the main body 321 in the-Z direction. The mounting stands 325a and 325b are located at or near the center of the bottom side 328 to accommodate the mounting assembly 350b.

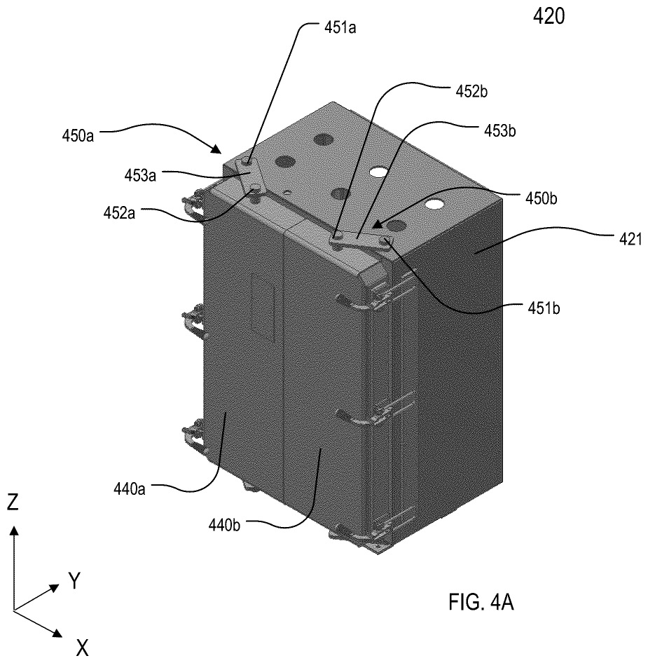

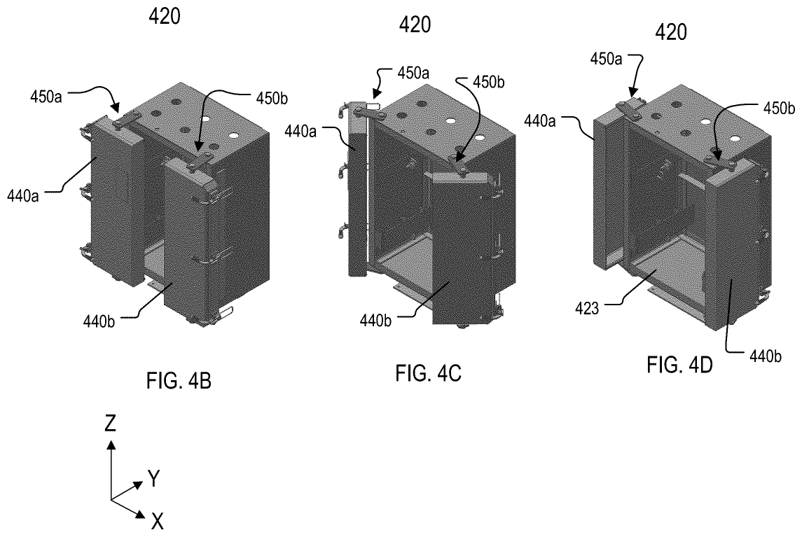

FIG. 4A is a perspective view of a housing 420. The housing 420 includes a main body 421 and doors 440a and 440b. FIG. 4A shows the doors 440a and 440b in a closed position. In the closed position, the doors 440a and 440b completely cover an opening 423. The opening 423 is labeled in FIG. 4D, which shows the doors 440a and 440b in the fully open position. The housing 420 includes a mounting assembly 450a and a mounting assembly 450b.

The mounting assembly 450a includes a connection point 451a, a connection point 452a, and a link 453a that extends between the connection points 451a and 452a. Each connection point 451a and 452a is a pin joint. The connection point 451a connects the main body 421 to the link 453a. The connection point 452a connects the link 453a to the door 440a.

The mounting assembly 450b includes a connection point 451b, a connection point 452b, and a link 453b that extends between the connection points 451b and 452b. Each connection point 451b and 452b is a pin joint. The connection point 451b connects the main body 421 to the link 453b. The connection point 452b connects the link 453b to the door 440b.

Referring also to FIGS. 4B and 4C, to open the housing 420, the doors 440a and 440b are separated from the main body 421 by applying a force in the −Y direction. The door 440a is translated in the −X direction and the door 440b is translated in the X direction (FIG. 4B). The door 440a is rotated clockwise about the connection point 452a, and the door 440b is rotated counterclockwise about the connection point 452b (FIG. 4C and FIG. 4D). FIG. 4D shows the doors 440a and 440b in the fully open position, with the opening 423 unobscured. Using two doors (the doors 440a and 440b) results in a smaller load on each mounting assembly 450a and 450b as compared to an implementation in which one mounting assembly holds a single door.

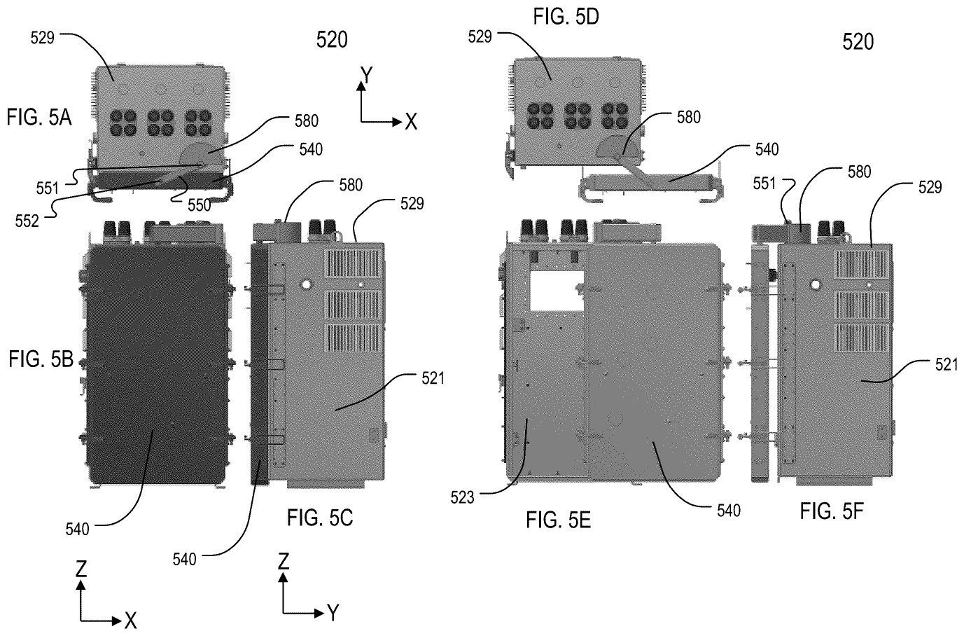

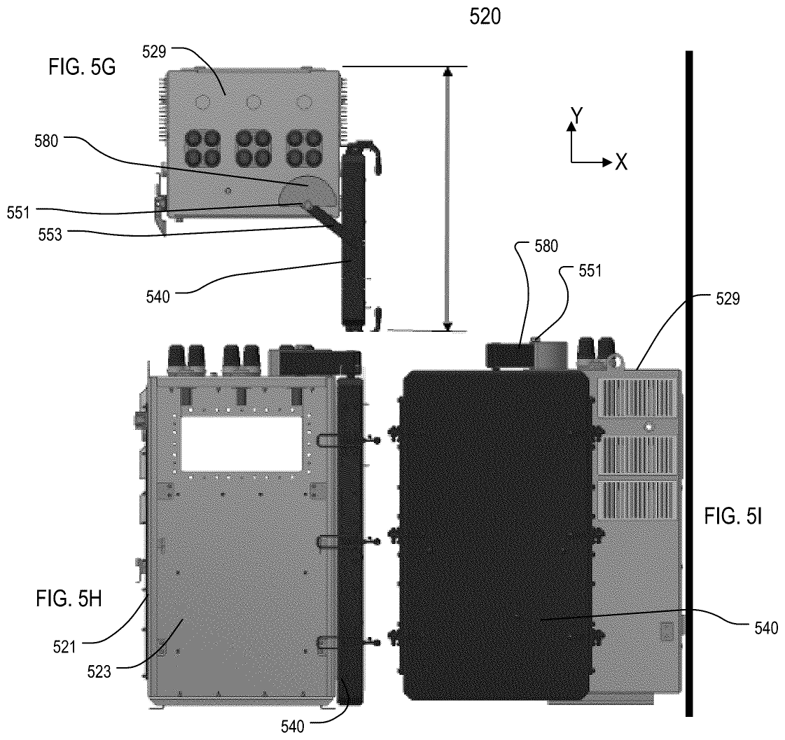

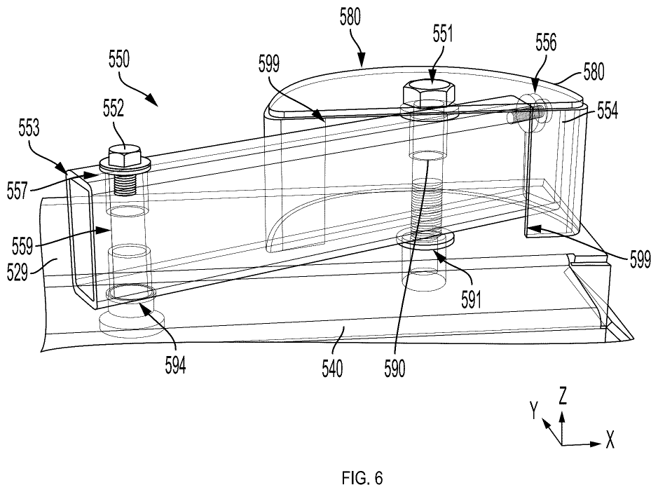

FIGS. 5A-5I and 6 relate to another example of a housing 520. The housing 520 includes a main body 521 and a door 540. FIGS. 5A, 5B, 5C show top, front, and side views, respectively, of the housing 520 with the door 540 in the closed position. FIGS. 5D, 5E, 5F show top, front, and side views, respectively, of the housing 520 with the door 540 in an interim position. FIG. 5G, 5H, 5I show top, front, and side views, respectively, of the housing 520 with the door 540 in the fully open position. When the door 540 is in the fully open positon, the housing 520 may have an extent of, for example, 50.375 inches in the Y direction and an opening 523 to an interior of the housing 520 is unobstructed. The extent of the housing 520 in the Y direction with the door 540 in the fully open position is less than in a housing that uses a traditional door mounting system.

The door 540 is movably mounted to the housing 520 with a mounting assembly 550 that includes a link 553. Due to the configuration of the mounting assembly 540, the extent of the housing 520 in the Y direction with the door 540 in the fully open position is about 15% less than it would be if a traditional door mounting system was used. The mounting assembly 550 also includes two connecting points 551 and 552, which are shown in FIG. 6. The mounting assembly 550 includes a hinge housing 580 that is welded or otherwise attached to a top side 529 of the main body 521.

Referring also to FIG. 6, a perspective view of the mounting assembly 550 and the hinge housing 580 is shown. The mounting assembly 550 includes a connection point 551, a connection point 552, and a link 553 that extends between the connection point 551 and the connection point 552. The link 553 is a metal tube. For example, the link 553 may be a metal tube with a rectangular cross-section. The connection point 551 is a pin joint that includes a bolt 590 that extends through the link 553 and into a threaded receptacle or nut 591 in or on the top side 529 of the main body 521. The link 553 is able to rotate about the bolt 590.

The connection point 552 includes a post or pin 559 that extends through the link 553 and into a fitting 594 on the door 540. The link 553 is able to rotate about the pin 559 and the door 540 is able to rotate relative to the pin 559. The fitting 594 may be, for example, a brass fitting. The pin 559 may extend through a brass bushing on the link 553 to reduce friction that could otherwise occur when the link 553 rotates about the pin 559.

The hinge housing 580 is a semi-circular structure that is open on one side and receives an end 554 of the link 553. The end 554 of the link 553 moves about an arc defined by the inner surface of the hinge housing 580, and the ends of the arc may be closed with stops or walls 599 to limit the motion of the link 553. A ball bearing 556 is at the end 554 of the link 553 and is between the end 554 and the inner surface of the hinge housing 580. The ball bearing 556 applies a force in the Z direction to counter the force in the −Z direction that the door 540 applies to the link 553. This prevents the door 540 from sagging. The ball bearing 556 also may facilitate smooth movement of the link 553 in the hinge housing 580.

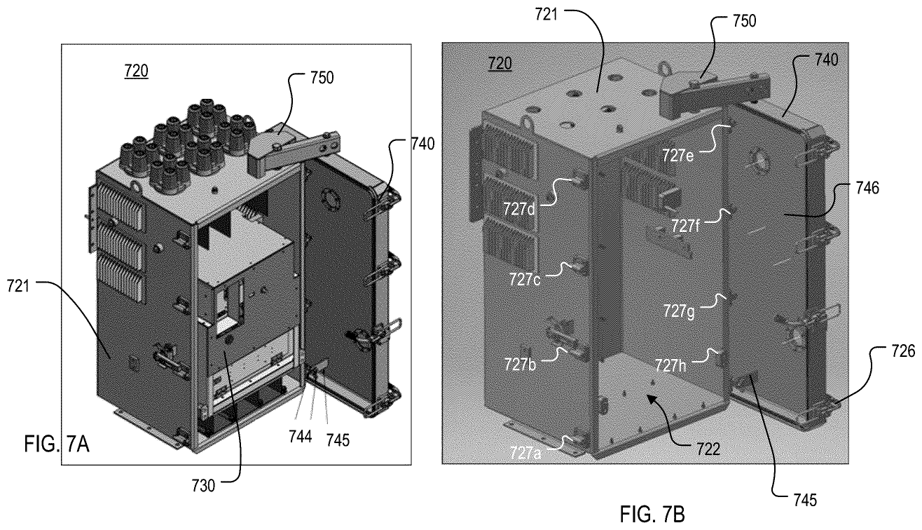

FIGS. 7A and 7B are perspective views of a housing 720. The housing 720 includes a main body 721 and a door 740 that is attached to the main body 721 with a mounting assembly 750. The mounting assembly 750 is similar to the mounting assembly 550. The mounting assembly 750 allows the door 740 to be moved between an opened position (such as shown in FIGS. 7A and 7B) and a closed position. The housing 720 includes an interior 722 that receives an electrical apparatus 730. FIG. 7A shows the housing 720 with the electrical apparatus 730 in the interior 722, and FIG. 7B shows the housing 720 without the electrical apparatus 730 in the interior 722. When the door 740 is in the opened position (such as shown in FIGS. 7A and 7B), the interior 722 is accessible. When the door 740 is in the closed position, the interior 722 is enclosed and is not accessible from the outside of the housing 720. The main body 721 also includes fasteners (each of which may be, for example, a latch/bolt block) 727a-727h that interact with corresponding latches or clips 726 on the door 740 to secure the door 740 to the main body 721 in the closed position.

The door 740 includes a limiting mechanism 745 that restricts unnecessary and/or unintentional movement of the door 740 when the door 740 is in the opened position. The limiting mechanism 745 extends from an interior surface 746 of the door 740. The interior surface 746 faces into the interior 722 when the door 740 is in the closed position. The limiting mechanism 745 may be, for example, a stop plate that extends substantially perpendicularly from the interior surface 746. The limiting mechanism 745 may be, for example, a stop plate, a block, or a rod.

The limiting mechanism 745 can be attached to the main body 721 while the door 740 is in the opened position to limit or prevent unintentional motion of the door 740. For example, the fastening system 744 may be attached to one of the fasteners 727e-727h on the main body 721 with, for example, a bolt, screw, and/or lock nut. The limiting mechanism 745 is removed prior to closing the door 740 or otherwise intentionally moving the door 740.

In the example shown, the limiting mechanism 745 is positioned on the interior surface 746 such that the limiting mechanism 745 is aligned with the lowest fastener (labeled 727h). This positioning may make it easier for the operator to attach the limiting mechanism 744 to the fastener 727. However, the limiting mechanism 745 may be positioned to be aligned with any of the fasteners 727e-727h. Moreover, the door 740 may include more than one limiting mechanism 745, each positioned to be aligned with one of the fasteners 727e-727h when the door 740 is in the opened position.

These and other implementations are within the scope of the claims. For example, any of the housings 220, 320, 420, 520 may include a limiting mechanism similar to the limiting mechanism 745.

What is claimed is:

1. An apparatus comprising:
a main body comprising an interior configured to receive an electrical apparatus, the main body comprising at least one opening to the interior;
a door configured to overlap the at least one opening to the interior in a first position and to not overlap the at least one opening to the interior in a second position; and
a mounting assembly comprising:
a first articulating connection attached to the main body;
a second articulating connection attached to the moveable door; and
a link between the first articulating connection and the second articulating connection, wherein the mounting assembly is configured to permit the door to move laterally relative to the main body and to rotate about the second articulating connection to transition from the first position and the second position.

2. The apparatus of claim 1, wherein each of the first articulating connection and the second articulating connection comprises a pin joint.

3. The apparatus of claim 2, wherein a first pin passes through the link and is attached to the main body to connect the link and the main body, and a second pin passes through the link and is attached to the door to connect the link and the door.

4. The apparatus of claim 1, wherein the mounting assembly is a first mounting assembly, and the apparatus further comprises a second mounting assembly.

5. The apparatus of claim 4, wherein the first mounting assembly is attached to one end of the door and to one end of the main body, and the second mounting assembly is attached to a different end of the door and to a different end of the main body.

6. The apparatus of claim 4, wherein the door comprises a first door and a second door, and the first mounting assembly is attached to the first door and the main body, and the second mounting assembly is attached to the second door and the main body.

7. The apparatus of claim 1, further comprising a hinge housing configured to receive an end of the link, and wherein the link is configured to move through an arc in the hinge housing.

8. The apparatus of claim 1, wherein the first position is a closed position, and the apparatus further comprises: a door fastening system configured to secure the door to the main body when the door is in the closed position.

9. The apparatus of claim 8, further comprising a motion limiting system that extends from the door and is configured to be attached to the door fastening system when the door is in the second position, and, when attached to the door fastening system, the motion limiting system prevents the door from moving from the second position to the first position.

10. The apparatus of claim 1, wherein the door is substantially planar, the door is in a first plane in the first position, and the door is in a second plane in the second position, and wherein the first plane and the second plane are perpendicular to each other.

11. The apparatus of claim 1, wherein the main body comprises a plurality of sides, and the mounting assembly is configured to allow the door to move laterally relative to two adjacent sides of the main body.

12. The apparatus of claim 11, wherein the two adjacent sides are two orthogonal sides of the main body.

13. A mounting assembly for a housing of an electrical apparatus, the mounting assembly comprising:
a link;
a first connection assembly configured to attach to a main body of the housing and to the link; and
a second connection assembly configured to attach to a door and to the link, wherein the mounting assembly is configured such that the door rotates relative to an axis of the second connection assembly and moves laterally relative to the main body.

14. The mounting assembly of claim 13, wherein the mounting assembly is configured to allow the door to move laterally relative to two orthogonal sides of the main body.

15. The mounting assembly of claim 14, wherein the first connection assembly comprises a first pin assembly that passes through the link at attaches to the main body; the second connection assembly comprises a second pin assembly that passes through the link and attaches to the door; and the link is configured to rotate relative to the first pin assembly and the second pin assembly.

16. The mounting assembly of claim 15, further comprising a hinge housing and a bearing, and wherein the first pin assembly is attached to the hinge housing and the bearing is between the link and an inner surface of the hinge housing.

17. A system comprising:
an electrical apparatus; and
a housing for the electrical apparatus, the housing comprising:
a main body comprising an interior;
a door configured to move between a closed position and an opened position, wherein the electrical apparatus is enclosed in the interior when the door is in the closed position; and
a mounting assembly comprising:
a first articulating connection attached to the main body;
a second articulating connection attached to the moveable door; and
a link attached to the first articulating connection and the second articulating connection, wherein the mounting assembly is configured to permit the door to move laterally relative to the main body and to rotate about the second articulating connection to transition the door from the closed position to the opened position.

18. The system of claim 17, further comprising a limiting apparatus that prevents the door from moving out of the opened position until the limiting apparatus is removed.

19. The system of claim 17, wherein the link comprises a bar that extends from a first end to a second end; and the system further comprises: a hinge housing attached to a top side of the main body, and a bearing; and wherein the first end of the bar is in the hinge housing with the bearing between the bar and an inner side of the hinge housing.

20. The system of claim 17, wherein the main body comprises a plurality of sides, and the mounting assembly is configured to allow the door to move laterally relative to two adjacent sides of the main body.
